(19) United States
(12) Patent Application Publication
(10) Pub. No.: US 2016/0012908 A1
(43) Pub. Date: Jan. 14, 2016

(54) E-FUSE ARRAY CIRCUIT AND SEMICONDUCTOR MEMORY APPARATUS HAVING THE SAME

(71) Applicant: SK hynix Inc., Icheon-si Gyeonggi-do (KR)

(72) Inventor: Hyuk Choong KANG, Icheon-si Gyeonggi-do (KR)

(21) Appl. No.: 14/514,487

(22) Filed: Oct. 15, 2014

(30) Foreign Application Priority Data
Jul. 9, 2014 (KR) 10-2014-0086094

(51) Int. Cl. G11C 17/16; G11C 29/00; G11C 29/42; G11C 17/18

(52) U.S. Cl. CPC G11C 17/16; G11C 17/18; G11C 29/787; G11C 29/42

(57) ABSTRACT

An E-fuse array circuit includes a driving block arranged in a predetermined portion of a semiconductor substrate, a normal fuse array configured to one side of the driving block, and an auxiliary circuit part arranged in an other side of the driving block to a direction facing an arrangement direction of the normal fuse array.

### CROSS-REFERENCES TO RELATED APPLICATION

This application claims priority under 35 U.S.C. 119(a) to Korean application No. 10-2014-0086094, filed on Jul. 9, 2014, in the Korean intellectual Property Office, which is incorporated by reference in its entirety as set forth in full.

### BACKGROUND

1. Technical Field

Various embodiments of the inventive concept relate to a semiconductor integrated circuit device, and more particularly, to an electric fuse (E-fuse) array circuit and a semiconductor memory apparatus having the same.

2. Related Art

Fuses in metal fuses are cut by a laser. A programming state is classified according to the cutting of the fuse. Therefore, it is possible to program the fuses on a wafer level, but it is impossible to program the fuses after packaging.

To overcome drawbacks of the metal fuses, E-fuses are developed. The E-fuses are fabricated in a transistor form, and data is stored by changing a resistance between a gate and a drain/source.

In general, a power voltage is applied to a gate terminal of an E-fuse, and a ground voltage is applied to a drain terminal and a source terminal. When a voltage having a level to which a transistor is endurable is applied to the gate terminal, the E-fuse operates as a capacitor. However, a voltage having a high level to which a transistor is not endurable is applied to the gate terminal, a gate oxide of the transistor is broken, and the gate terminal and the drain/source terminal are short-circuited. Thus the E-fuse operates as a resistor. Therefore, current flows between the gate terminal and the drain/source terminals. Using these phenomena, the E-fuse classifies data through resistance values between the gate terminal and the drain/source terminals.

In recent years, the E-fuse having an array form is the trend.

### SUMMARY

According to an embodiment, there is provided an E-fuse array circuit. The E-fuse array circuit may include a driving block arranged in a predetermined region on a semiconductor substrate, a normal fuse array configured to one side of the driving block, and an auxiliary circuit part arranged in an other side of the driving block to a direction facing an arrangement direction of the normal fuse array.

According to an embodiment, there is provided a semiconductor memory apparatus. The semiconductor memory apparatus may include a plurality of banks arranged in a cell region of a semiconductor substrate in which the cell region and a peripheral region are defined. The semiconductor memory apparatus may also include an E-fuse array circuit arranged in the peripheral region and including a driving block arranged in a predetermined region of the semiconductor substrate, and a normal fuse array arranged close to one side of the driving block. Further, the semiconductor memory apparatus may include an auxiliary circuit part arranged in an other side of the driving block to a direction facing an arrangement direction of the normal fuse array.

In an embodiment, an electric (E-fuse) array circuit may include a driving block configured in a predetermined region of a semiconductor substrate. The E-fuse array circuit may also include a fuse array arranged near a side of a driving block. In addition, the E-fuse array circuit may include an error check correction (ECC) circuit unit and a redundancy fuse array arranged on an other side of the driving block.

### BRIEF DESCRIPTION OF THE DRAWINGS

FIG. 1 is a layout diagram illustrating an E-fuse array circuit according to an embodiment;

FIG. 2 is a view illustrating a configuration of an error check and correction (ECC) circuit unit according to an embodiment;

FIGS. 3 to 5 are views illustrating configurations of semiconductor memory apparatuses including an E-fuse array circuit according to embodiments;

FIG. 6 is a view illustrating a configuration of a driving block according to an embodiment;

FIG. 7 is a view illustrating a configuration of a controller according to an embodiment;

FIG. 8 is a view illustrating a method of manufacturing an E-fuse array circuit according to an embodiment; and

FIG. 9 illustrates a block diagram of a system employing a memory controller circuit in accordance with an embodiment of the invention.

### DETAILED DESCRIPTION

Various embodiments will be described in greater detail with reference to the accompanying drawings. Various embodiments are described with reference to cross-sectional illustrations that are schematic illustrations of various embodiments (and intermediate structures). As such, variations from the shapes of the illustrations as a result, for example, of manufacturing techniques and/or tolerances, are to be expected. Thus, embodiments should not be construed as limited to the particular shapes of regions illustrated but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present. It is also noted that in this specification, “connected/electrically coupled” refers to one component not only directly electrically coupling another component but also indirectly electrically coupling another component through an intermediate component. In addition, a singular form may include a plural form, and vice versa as long as it is not specifically mentioned.

The inventive concept is described with reference to cross-section and/or plan illustrations that are schematic illustrations of idealized embodiments of the inventive concept. However, embodiments of the inventive concept should not be limited construed as limited to the inventive concept. Although a few embodiments of the inventive concept will be shown and described, it will be appreciated by those of ordinary skill in the art that changes may be made in these various embodiments without departing from the principles and spirit of the inventive concept.

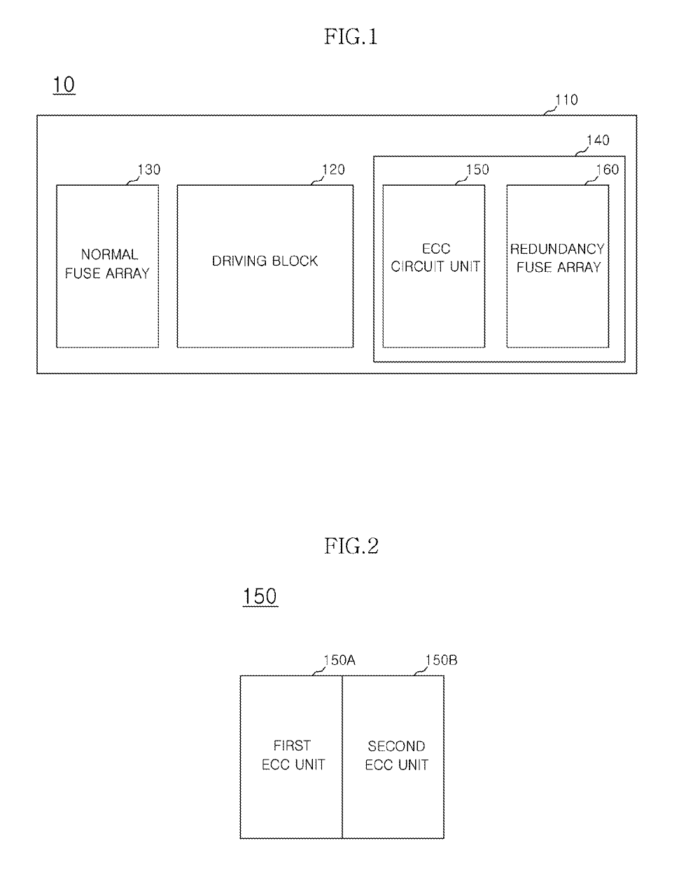

Referring to FIG. 1, a layout diagram illustrating an E-fuse array circuit according to an embodiment is shown.

An E-fuse array circuit 10 may include a driving block 120 arranged in a predetermined region of a semiconductor substrate 110. The E-fuse array circuit 10 may also include a normal fuse array 130 arranged closed to one side of the driving block 120.

An auxiliary circuit part 140 may be arranged in the other side of the driving block 120, specifically, to a direction facing a direction in which the normal fuse array 130 is arranged.

Although the normal fuse array 130 is arranged closed to one side of the driving block 120, and the auxiliary circuit part 140 is arranged closed to the other side of the driving block 120, the arrangement location of the auxiliary circuit part 140 is not limited thereto. More specifically, the auxiliary circuit part 140 may not be arranged close to the driving block 120, and may be arranged to be spaced apart from the other side of the driving block 120. In an embodiment, the auxiliary circuit part 140 may be arranged to be spaced from the driving block 120 in a region of the semiconductor substrate 110 in which circuit design density is low.

The auxiliary circuit part 140 may not be used or may be removed after manufacturing the E-fuse array circuit. When the auxiliary circuit part 140 is removed, circuit parts for other purposes may be formed in the corresponding region from which the auxiliary circuit part 140 is removed.

The auxiliary circuit part 140 may include an error check and correction (ECC) circuit unit 150 and a redundancy fuse array 160.

The ECC circuit unit 150 may be configured to check and correct an error of data stored in the normal fuse array 130.

The redundancy fuse array 160 may be used to replace a fuse in which a fail occurs when the fail occurs in the unit fuse constituting the normal fuse array 130. When the redundancy fuse array 160 is included in the ECC circuit unit 150, the ECC circuit unit 150 may be configured to check and correct an error of data stored in the redundancy fuse array 160 in addition to the normal fuse array 130.

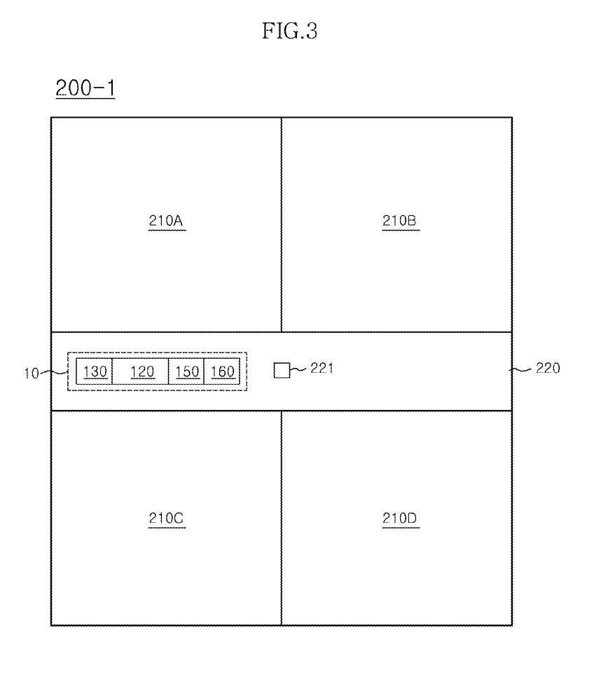

Referring to FIG. 2, a view illustrating a configuration of an ECC circuit unit according to an embodiment is shown.

The ECC circuit unit 150 may include a first ECC unit 150A which checks and corrects an error of the normal fuse array 130. The ECC circuit unit 150 may also include a second ECC unit 150B which checks and corrects an error of the redundancy fuse array 160.

The first ECC unit 150A may be formed close to or spaced from the other side of the driving block 120. Further, the first ECC unit 150A may be arranged closer to the normal fuse array 130 than the second ECC unit 150B. More specifically, of the auxiliary circuit part 140 arranged in the other side of the driving block 120, the first ECC unit 150A may be arranged closest to the driving block 120.

The second ECC unit 150B may be arranged between the first ECC unit 150A and the redundancy fuse array 160, but the arrangement of the second ECC unit 150B is not limited. The second ECC unit 150B may be arranged close to or spaced from the first ECC unit 150A. The second ECC unit 150B may be arranged close to or spaced from the redundancy fuse array 160.

When an error occurs in data stored in the normal fuse array 130 or a defect occurs in a fuse cell, the error or defect in the normal fuse array 130 may be supplemented through the ECC circuit unit 150 and the redundancy fuse array 160.

When the error or defect does not occur in the normal fuse array 130, the auxiliary circuit part 140 is not necessary. In an embodiment, after the E-fuse array circuit 10 is designed, it is checked whether or not the auxiliary circuit part 140 is necessary through revision. At least a portion of the auxiliary circuit part 140 may be deleted according to whether or not the auxiliary circuit part 140 is necessary. After the at least a portion of the auxiliary circuit part 140 is deleted, circuits for other purposes, for example, additional circuits such as a reservoir capacitor or a spare logic may be added to the region from which the auxiliary circuit part 140 is deleted.

The phrase “at least a portion of the auxiliary circuit part 140 is deleted” may mean that at least one of the ECC circuit unit 150 and the redundancy fuse array 160 is removed. Further, when the ECC circuit unit 150 includes the first ECC unit 150A and the second ECC unit 150B, at least one of the first ECC unit 150A and the second ECC unit 150B may be removed.

The ECC circuit unit 150 and the redundancy fuse array 160 occupy about a quarter of a total area of the E-fuse array circuit 10. Therefore, when the auxiliary circuit part 140 is not necessary and thus removed, an area occupied with the E-fuse array circuit 10 may be reduced to three quarters of the total area.

Even when the ECC circuit unit 150 and the redundancy fuse array 160 are necessary, the auxiliary circuit part 140 may be arranged in a region of the semiconductor substrate 100 with a low circuit design density. That is, an area occupied with a part arranged in a region having the high circuit design density, more specifically, the driving block 120 and the normal fuse array 130 may be reduced to about three quarters of the total area.

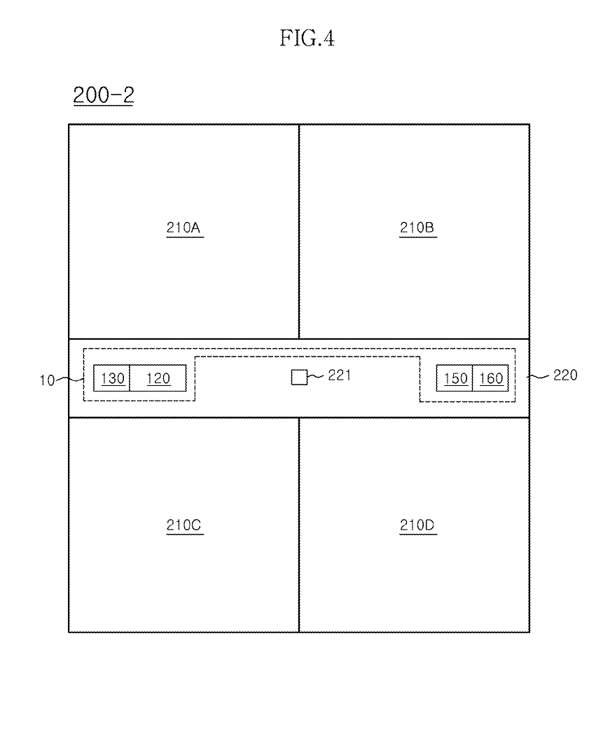

Referring to FIGS. 3 to 5, views illustrating configurations of semiconductor memory apparatuses including an E-fuse array circuit according to embodiments are shown.

In FIG. 3, a semiconductor memory apparatus 200-1 according to an embodiment is divided into cell regions 210A, 210B, 210C, and 210D, and a peripheral region 220. A plurality of banks 210A and 210B may be arranged in an upper side of the peripheral region 220 on the basis of the peripheral region 220. Further, a plurality of banks 210C and 210D may be arranged in a lower side of the peripheral region 200 on the basis of the peripheral region 220.

An E-fuse array circuit 10 may be arranged in the peripheral region 220.

The E-fuse array circuit 10 may include a driving block 120 and a normal fuse array 130 arranged close to one side of the driving block 120. Further, auxiliary circuit parts 150 and 160 may be arranged in the other side of the driving block 120.

The auxiliary circuit parts 150 and 160 may not be used or may be removed when it is determined that the auxiliary circuit parts 150 and 160 are not necessary through revision after design. When the auxiliary circuit parts 150 and 160 are removed, circuit parts for other purposes may be reconstructed in the region from which the auxiliary circuit parts 150 and 160 are removed.

When it is determined that at least a portion of the auxiliary circuit parts 150 and 160 may be removed or may not be used, the auxiliary circuit parts 150 and 160 may be controlled through a pad 221. A plurality of pads may be provided in the peripheral region 220. The E-fuse array circuit 10 may be controlled so that only the normal fuse array 130 is used or the normal fuse array 130 and the auxiliary circuit parts 150 and 160 are entirely used, according to a level of a signal applied to any one pad 221 among the plurality of pads.

FIG. 4 illustrates a configuration of a semiconductor memory apparatus 200-2 according to an embodiment. FIG. 4 also illustrates an example in which the auxiliary circuit parts 150 and 160, which may be referred to as the auxiliary circuit part (see 140 of FIG. 1), are arranged to be spaced from a driving block 120 in the other side of the driving block 120.

In a semiconductor memory apparatus 200-3 of FIG. 5, the ECC circuit unit 150 constituting auxiliary circuit parts 150 and 160, which may be referred to as the auxiliary circuit part (see 140 of FIG. 1), includes a first ECC unit 150A and a second ECC unit 150B, and auxiliary circuit parts 150A, 150B, and 160, (which may be referred to as the auxiliary circuit part see 140 of FIG. 1), are dispersedly arranged. In particular, the first ECC unit 150A may be arranged close to the other side of a driving block 120.

The auxiliary circuit parts 150 and 160 in FIGS. 3 to 5 may be deleted after revision. Further, circuit parts for other purposes may be redesigned in the region in which the auxiliary circuit parts 150 and 160 are removed.

FIGS. 4 and 5 have described that the auxiliary circuit part 140 of the E-fuse array circuit 10 is controlled through the pad 221. When the auxiliary circuit part 140 of the E-fuse array circuit 10 is not used, the E-fuse array circuit 10 may be controlled through the driving block 120. A detailed description will be made below.

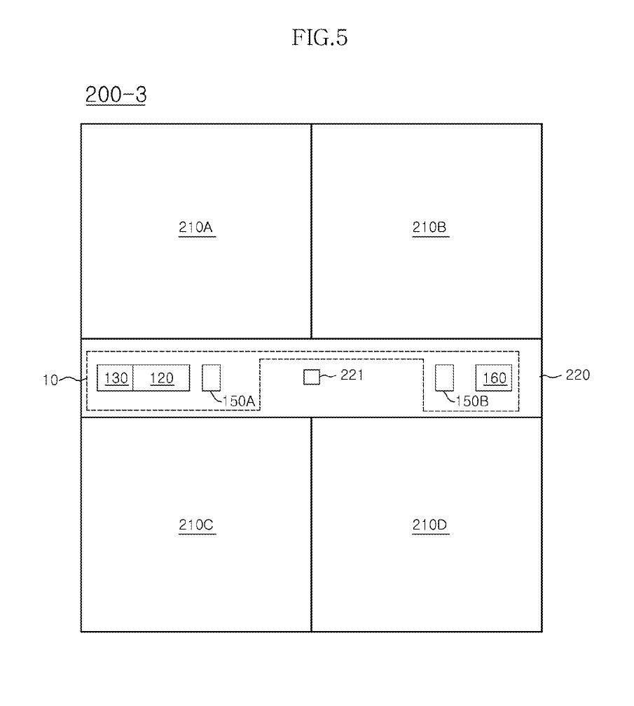

Referring to FIG. 6, the driving block 120 may include a selecting and sensing unit 121, a bias providing unit 123, and a controller 125,

The selecting and sensing unit 121 selects a unit fuse cell constituting the normal fuse array 130 or the redundancy fuse array 160 in response to an address signal. The selecting and sensing unit 121 also senses data stored in the selected unit fuse cell.

The bias providing unit 123 provides a voltage for a program or read operation to or from the normal fuse array 130 or the redundancy fuse array 160.

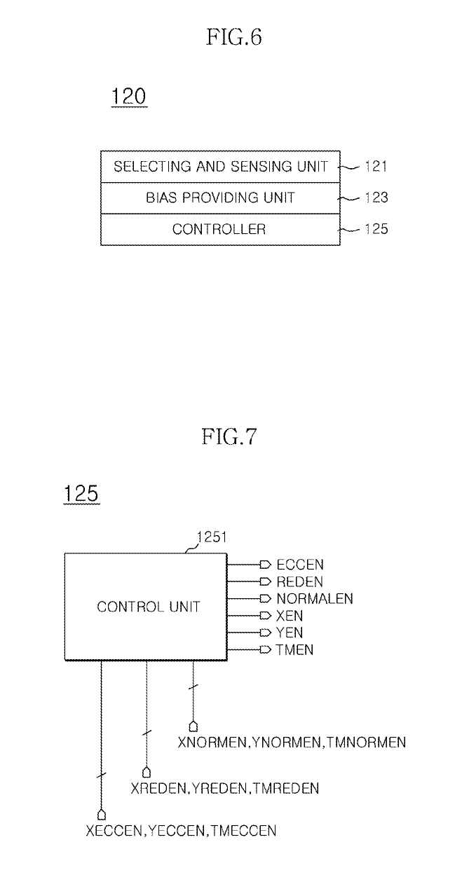

The controller 125 controls the selecting and sensing unit 121 and the bias providing unit 123. The controller 125 also controls the normal fuse array 130 and the auxiliary circuit part 140 as illustrated in FIG. 7.

Referring to FIG. 7, the controller 125 may include a control unit 1251. The control unit 1251 may output an ECC enable signal ECCEN, a redundancy enable signal REDEN, and a normal signal NORMALEN, a column enable signal XEN, a row enable signal YEN, and a test mode enable signal TMEN in response to first to third ECC control signals XECCEN, YECCEN, and TMECCEN, first to third redundancy control signals XREDEN, YREDEN, and TMREDEN, and first to third normal control signal XNORMEN, YNORMEN, and TMNORMEN.

When at least a portion of the auxiliary part 140 such as the ECC circuit unit 150 and the redundancy fuse array 160 is not used or is removed, the controller 125 may disable a signal to enable the removed auxiliary circuit part, that is, the ECC enable signal ECCEN or the redundancy enable signal REDEN. Therefore, the driving of the auxiliary circuit part 140 due to generation of an unnecessary control signal may be prevented. Accordingly, power consumption according to the generation of the unnecessary control signal may be prevented.

The configurations of the controllers illustrated in FIGS. 6 and 7 are not limited. Any configuration which may control the normal fuse array 130 and the auxiliary circuit part 140 may be adopted.

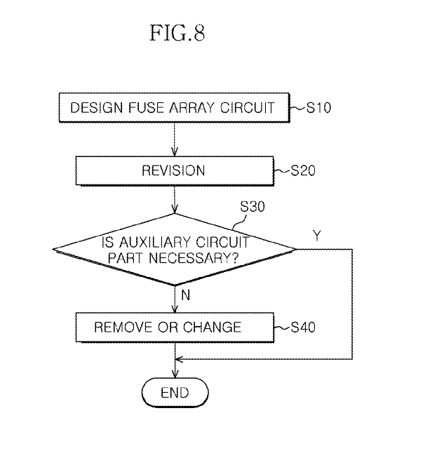

Referring to FIG. 8, a flowchart illustrating a method of manufacturing an E-fuse array circuit according to an embodiment is shown.

First, an E-fuse array circuit is designed on a semiconductor substrate (S10). The E-fuse array circuit may include the driving block 120, the normal fuse array 130 arranged closed to one side of the driving block 120, and an auxiliary circuit part 140 arranged close to or spaced from the driving block 120 in the other side of the driving block 120 to a direction facing an arrangement direction of the normal fuse array 130 on the basis of the driving block 120 as illustrated in FIGS. 1 and 3 to 6.

When the E-fuse array circuit is designed, revision is performed on a wafer level (S20).

When it is determined that at least a portion of the auxiliary circuit part 140 is unnecessary as a result of the revision (S30), the at least a portion of the auxiliary circuit part 140, determined as the unnecessary part, is removed or is changed to other circuit part (S40).

When it is determined that the entire auxiliary circuit part 140 is necessary as a result of the revision (S30), the auxiliary circuit part 140 is maintained as it is.

Therefore, in an embodiment, when the auxiliary circuit is unnecessary, only the normal fuse array 130 and the driving block 120 constitute the E-fuse array circuit. Further, even when the at least a portion of the auxiliary circuit part 140 is necessary, the auxiliary circuit part 140 is arranged in a region having the low circuit design density. Accordingly, an area efficiency of the region, in which the normal fuse array 130 and the driving block 120 are arranged, may be improved.

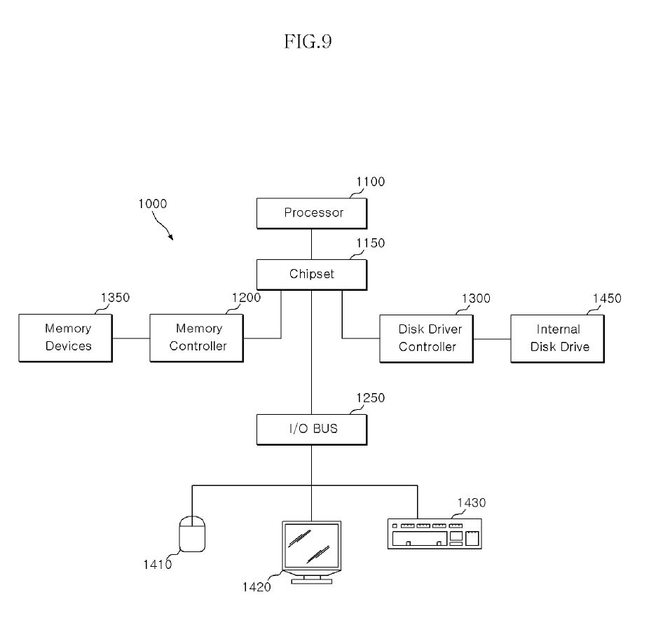

Referring to FIG. 9, a system 1000 may include one or more processors 1100. The processor 1100 may be used individually or in combination with other processors. A chipset 1150 may be operably electrically coupled to the processor 1100. The chipset 1150 is a communication pathway for signals between the processor 1100 and other components of the system 1000. Other components may include a memory controller 1200, an input/output (“I/O”) bus 1250 and a disk drive controller 1300. Depending on the configuration of the system 1000, any one of a number of different signals may be transmitted through the chipset 1150.

The memory controller 1200 may be operably electrically coupled to the chipset 1150. The memory controller 1200 can receive a request provided from the processor 1100 through the chipset 1150. The memory controller 1200 may be operably electrically coupled to one or more memory devices 1350. The memory device 1350 may include one of the semiconductor memory apparatuses described above.

The chipset 1150 may also be electrically coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420 and 1430.

The disk drive controller 1300 may also be operably electrically coupled to the chipset 1150. The disk drive controller 1300 may serve as the communication pathway between the chipset 1150 and one or more internal disk drives 1450. The disk drive controller 1300 and the internal disk drives 1450 may communicate with each other or with the chipset 1150 using virtually any type of communication protocol.

The above embodiments of the invention are illustrative and not limitative. Various alternatives and equivalents are possible. The invention is not limited by the embodiments described. Nor is the invention limited to any specific type of semiconductor device. Other additions, subtractions, or modifications are obvious in view of the disclosure and are intended to fall within the scope of the appended claims.

What is claimed is:

1. An electric fuse (E-fuse) array circuit comprising:
a driving block arranged in a predetermined region of a semiconductor substrate;
a normal fuse array configured to one side of the driving block;
an auxiliary circuit part arranged in an other side of the driving block to a direction facing an arrangement direction of the normal fuse array.

2. The E-fuse array circuit of claim 1, wherein the auxiliary circuit part is arranged closed to or spaced from the driving block in the other side of the driving block.

3. The E-fuse array circuit of claim 1, wherein the auxiliary circuit part includes an error check and correction (ECC) circuit unit and a redundancy fuse array.

4. The E-fuse array circuit of claim 3, wherein at least one of the ECC circuit unit and the redundancy fuse array is arranged closed to or space from the driving block in the other side of the driving block.

5. The E-fuse array circuit of claim 3, wherein the ECC circuit unit includes a first ECC unit and a second ECC unit,
wherein the first ECC unit is arranged closer to the normal fuse array than the second ECC unit.

6. The E-fuse array circuit of claim 1, wherein the driving block includes a controller,
wherein the auxiliary circuit part is configured to be enabled or disabled by the controller.

7. A semiconductor memory apparatus comprising:
a plurality of banks arranged in a cell region of a semiconductor substrate in which the cell region and a peripheral region are defined; and
an electric fuse (E-fuse) array circuit arranged in the peripheral region, and including a driving block arranged in a predetermined region of the semiconductor substrate, a normal fuse array arranged close to one side of the driving block, and an auxiliary circuit part arranged in an other side of the driving block to a direction facing an arrangement direction of the normal fuse array.

8. The semiconductor memory apparatus of claim 7, wherein the auxiliary circuit part is arranged close to or spaced apart from the driving block in the other side of the driving block.

9. The semiconductor memory apparatus of claim 7, wherein the auxiliary circuit part includes an error check and correction (ECC) circuit unit and a redundancy fuse array.

10. The semiconductor memory apparatus of claim 9, wherein at least one of the ECC circuit unit and the redundancy fuse array is arranged close to or spaced from the driving block in the other side of the driving block.

11. The semiconductor memory apparatus of claim 9, wherein the ECC circuit unit includes a first ECC unit and a second ECC unit,
wherein the first ECC unit is arranged closer to the normal fuse array.

12. The method of claim 7, further comprising:
a pad arranged in the peripheral region and receiving a control signal for the E-fuse array circuit.

13. The method of claim 7, wherein the driving block includes a controller configured to enable or disable the auxiliary circuit part.

14. An electric fuse (E-fuse) array circuit comprising:
a driving block configured in a predetermined region of a semiconductor substrate;
a fuse array arranged near a side of a driving block; and
an error check correction (ECC) circuit unit and a redundancy fuse array arranged on an other side of the driving block.

15. The E-fuse array circuit of claim 14, wherein ECC circuit unit and the redundancy fuse array are arranged in a region of the semiconductor substrate with a low circuit design density.

16. The E-fuse array circuit of claim 14, wherein the redundancy fuse array is configured to replace a fuse in which a fail occurs when the fail occurs in the fuse array.

17. The E-fuse array circuit of claim 14, wherein the ECC circuit unit is configured to correct an error of data stored in the redundancy fuse array.

18. The E-fuse array circuit of claim 17, where the ECC circuit includes a first ECC unit to correct an error of data of the fuse array and a second ECC unit to correct the error of data of the redundancy fuse array.

19. The E-fuse array circuit of claim 14, wherein the ECC circuit unit and the redundancy fuse array are configured to supplement an error in data stored in the fuse array.

20. The E-fuse array circuit of claim 18, wherein the first ECC unit is configured on the other side of the driving block.
